(19) United States
(12) Patent Application Publication
(10) Pub. No.: US 2009/0154872 A1
(43) Pub. Date: Jun. 18, 2009

(54) ELECTRONIC DEVICE PACKAGE AND METHOD OF FORMATION

(76) Inventors: David S. Sherrer, Radford, VA (US); Carl E. Gaebe, Blacksburg, VA (US); James W. Getz, Blacksburg, VA (US); Larry J. Rasnake, Blacksburg, VA (US); William K. Hogan, Merritt Island, FL (US)

Correspondence Address: SHERR & VAUGHN, PLLC, 620 HERNDON PARKWAY, SUITE 200, HERNDON, VA, 20170, US

(21) Appl. No.: 12/338,918

(22) Filed: Dec. 18, 2008

Related U.S. Application Data
(60) Provisional application No. 61/008,053, filed on Dec. 18, 2007.
(60) Provisional application No. 61/009,619, filed on Dec. 31, 2007.
(60) Provisional application No. 61/009,621, filed on Dec. 31, 2007.
(60) Provisional application No. 61/066,945, filed on Feb. 24, 2008.

(51) Int. Cl. G02B 6/12; G02B 7/00; H05K 5/06

(52) U.S. Cl. 385/14; 174/50.63; 359/514

(57) ABSTRACT

Provided are electronic device packages and their methods of formation. The electronic device packages include a sealed volume enclosing an electronic device and a feedthrough into the sealed volume for electrical connection of the electronic device. Provided are optoelectronic device packages and their methods of formation. The optoelectronic device packages include a first substrate and lid attached to the first substrate forming an enclosed volume. An optoelectronic device is disposed within the enclosed volume and a wick stop for preventing solder flow is provided. Provided are prism-coupled optical assemblies which allow for the coupling of light between an optical component, such as a laser, and an integrated optical waveguide through a prism.

The present application claims priority under 35 U.S.C. 119 to U.S. Provisional Patent Ser. No. 61/008,053 entitled “ELECTRONIC DEVICE PACKAGE AND METHOD OF FABRICATION” (filed Dec. 18, 2007), U.S. Provisional Patent Ser. No. 61/009,619 entitled “OPTOELECTRONIC DEVICE PACKAGES AND METHODS OF FORMATION” (filed Dec. 31, 2007), U.S. Provisional Patent Ser. No. 61/009,621 entitled “OPTOELECTRONIC DEVICE PACKAGES AND METHODS OF FORMATION” (filed Dec. 31, 2007), and U.S. Provisional Patent Ser. No. 61/066,945 entitled PRISM-COUPLED OPTICAL ASSEMBLIES AND METHODS OF FORMATION” (filed Feb. 24, 2008), which are hereby incorporated by reference in their entireties.

### BACKGROUND

Related hermetically sealed chip-scale and wafer-level packages containing electronic devices, for example, micro-electro-mechanical systems (MEMS), integrated circuits (ICs) and optoelectronic devices typically include an enclosed volume which is hermetically sealed, formed between a base substrate and lid, with the electronic device being disposed in the enclosed volume. These packages provide for containment and protection of the enclosed devices from contamination and water vapor present in the atmosphere outside of the package. The presence of contamination and water vapor in the package can give rise to problems such as corrosion of metal parts as well as optical losses in the case of optical MEMS and optoelectronic devices and other optical components. In the case of a MEMS device having moving parts, a low pressure operating environment is typically desired, and performance can degrade significantly as pressure within the device enclosure increases as a result of leakage from the outside atmosphere. Some MEMS devices contain one or more substances in the hermetic cavity for preventing stiction of the moving elements. Loss of these substances from the sealed volume as a result of leakage can adversely impact device performance, and its prevention is therefore desired.

For purposes of providing electrical connectivity between the electronic device enclosed in the package and the outside world, an electrical feedthrough between the package interior and exterior is utilized. This can be problematic in that the feedthrough can itself be a source of leakage between the enclosed volume and package exterior. It is therefore advantageous that the device package seal not be compromised by the electrical feedthrough. Related electrical feedthroughs for hermetic packages use conductive vias in a hermetically sealed optoelectronic package. The optoelectronic device is disposed on a substrate and is enclosed in a hermetic volume by a lid attached to the substrate. Conductive vias extend through the substrate to provide electrical connectivity to the device. The formation of conductive vias, however, has various drawbacks. For example, the manufacturing process for such structures can be very complex, time consuming and costly, requiring two-sided processing for the electrical conductors. In addition, the minimum size attainable for the vias is limited by the aspect ratio of the via etching process. Additional steps for introducing vias into a complex device wafer such as a MEMS wafer can have significant impact on yield, require redesign of an established manufacturing process and be performance-limited due to a limited set of compatible processes available to add the vias to the device wafer. It is therefore desirable to have a die- or wafer-level hermetic lid technology that requires minimal processing and design changes to the device wafer.

For ease of manufacture and cost reasons, it would be beneficial to form the electrical conductors or a primary portion thereof on the same surface of the device substrate as the electronic device. Such a process can be accomplished, for example, using standard metallization and patterning techniques. Because the electrical conductors in such a device would pass beneath the lid, an insulating material over the metal conductors would typically be used to bond the lid to the substrate in order to avoid short circuiting of the conductors, such as, for example, a solder glass frit ring to bond the lid to the base substrate. To ensure hermeticity of the seal in such a structure, the width of solder glass used is typically large. As a result, the number of die which can be formed on a single substrate in the case of a wafer-level process may be limited. In addition, outgassing of the residual binder material and low-temperature metal oxides of the solder glass into the cavity can produce contamination adversely impacting device performance. Further, solder glass may not provide a viable solution in cases where the use of lead-containing compounds is restricted, as lead oxide is an important constituent of most solder glass compounds. In RF and microwave devices, solder glass can also become problematic due to the combination of the high dielectric constant and long path length required in the sealing region producing performance-limiting parasitics such as excessive capacitance.

To maximize packing density of packages which can be formed on a single wafer, a metal-metal seal between the base substrate and package would be desirable. Owing to its relatively low permeability to gas, a metal seal ring between the substrate and lid would be expected to allow for a significant reduction in width and corresponding increase in number of die per substrate, in comparison with a solder glass frit ring. As mentioned above, however, a metal sealing ring in contact with conductors passing beneath the lid may cause shorting of the device.

The demand for increased communication bandwidth has driven the development of optical communications and optical networks. It is desirable to create all-optical networks and to develop optical circuits that are analogous to electrical networks and circuits. Electrical networks and circuits have benefited through the introduction of integrated circuits and the evolution of these circuits to provide increased density, while reducing cost. In analogy, optical networks and optical circuits have been developed using optical waveguides as an interconnect for routing, splitting and distribution of the optical signals. One form of such an optical circuit is a planar lightwave circuit (PLC) for which waveguide structures are fabricated on a substrate formed of silicon, glass, or other suitable materials. PLCs typically utilize discrete lasers and photodetectors that require alignment and attachment to the PLC to couple the light into and out of the waveguides.

An emerging technology, the photonic integrated circuit (PIC), integrates the PLC waveguides onto a substrate that also integrates electronic functions, such as drivers, amplifiers, switches, receivers, phase lock loops and the like, that form the communications network. PICs have now evolved to include other optical functions, for example, modulators, photodetectors, splitters, attenuators, multiplexers, demultiplexers, onto the same substrate integrated with the optical waveguides and electronic functions. To date, however, the integration of an optoelectronic device such as a laser into a PLC and PIC has not been achieved.

As the optoelectronic device to be integrated into a PLC or PIC, a hermetically sealed optoelectronic device is desired. Hermetically sealed chip-scale and wafer-level packages containing optoelectronic devices such as lasers are known. Such packages often include an enclosed volume which is hermetically sealed, formed between a base substrate and lid, with the optoelectronic device being disposed in the enclosed volume. These packages provide for containment and protection of the enclosed devices from contamination and water vapor present in the atmosphere outside of the package. The presence of contamination and water vapor in the package can give rise to problems such as corrosion of metal parts as well as optical losses for optical/optoelectronic components in the hermetic cavity. In addition, these packages are sometime sealed under vacuum or a controlled atmosphere to either allow proper operation or to meet the desired lifetime for the device.

One related optoelectronic package includes a cap with a light emitting device mounted in a recess in the cap. A wall of the recess is metallized to provide a light reflecting surface. A plate is attached to the cap using a metal or solder glass ring to define a hermetically sealed region in which the light emitting device is housed and a base is attached to the plate. The plate and base are transparent to a wavelength of light emitted by the light emitting device.

Low melting point metals such as solders are employed in hermetically sealed optoelectronic packages, for example, in solder pads for optoelectronic and electronic devices and in sealing rings used to form a hermetic seal between a base substrate and lid. The undesired flow of solders during formation of the package can have very deleterious effects. For example, in packages in which conductive traces extend between a base substrate and lid, solder may uncontrollably flow beneath the lid and contact the conductive traces, causing shorting of the device. Similarly, in the case of a turning mirror which may be formed on an inner surface of the lid, flowing solder during the lid sealing process can contaminate the mirror, causing obscuring of the beam and signal loss.

The use of planar lightwave circuits (PLCs) in optical communications and optical sensing is known. PLCs are the optical equivalent of an electronic chip, manipulating and processing light signals rather than electronic signals. They include a network of integrated optical waveguides formed in and/or on the substrate, along with various optical devices and functionalities interconnected by the waveguides. The optical devices may include both passive devices and active electro-optic devices which perform one or more functions such as reflection, focusing, collimating, beam splitting, wavelength multiplexing/demultiplexing, switching modulation, detection, and the like. PLCs are typically formed in a relatively thin layer of glass, polymer or semiconductor formed on or in a substrate. The substrate materials may be, for example, a semiconductor such as single-crystalline-silicon or a glass.

Light may be coupled into the PLC integrated optical waveguides by various techniques, such as edge-coupling via butt- or end fire-coupling, or surface-coupling via grating- or prism-coupling. In any coupling technique, optical loss is expected in propagating the light from one structure into another. Although edge-coupling is generally more efficient from an optical loss standpoint than surface-coupling, a compact design is difficult to achieve with edge-coupling, mechanical tolerances and attach processes can be difficult, and some applications will otherwise require the use of surface-coupling for coupling light into the PLC. Further, surface-coupling provides flexibility to the PLC designer since it eliminates the need for waveguides to be routed to the edge of the chip.

Of the two mentioned surface-coupling techniques, grating-coupling is the more common approach for coupling light into PLC waveguides. With this technique, the optical signals are surface-coupled into the PLC waveguides via a grating-coupler, which forms part of the PLC chip. The grating-couplers include plural elements designed to couple light into the waveguides along a predetermined optical path. Some of the elements vary in dimension, such as width or height, or in local index of refraction. While generally considered the best solution for surface-coupling with a PLC, grating-coupling is not ideal in that it is highly wavelength-sensitive and necessitates additional complexity in the PLC fabrication process.

In prism-coupling, the light beam is incident upon an optical element of high-index material in the form of a prism disposed in very close proximity to the PLC waveguide of interest to allow evanescent coupling of light from the prism to the waveguide. For evanescent coupling to occur, the medium separating the optical element from the waveguide must have a refractive index that is lower than those associated with the prism and the waveguide material. In addition, the refractive index of the prism must equal or exceed that of the waveguide material. To couple light efficiently from the optical element to the waveguide for a specified wavelength and waveguide thickness, light is made to be incident on the waveguide at a specific angle of incidence which can be achieved by varying the angle of incidence of the external beam on the angled facet of the prism. In this way, the beam inside the prism can be refracted at the desired angle.

Prism-coupling offers advantages over grating-coupling both in being capable of having less wavelength-sensitivity as well as allowing for eliminating the need for complex grating fabrication in PLC fabrication process. However, prism-coupling into planar waveguide devices has generally been limited to testing of slab waveguide materials, measuring optical film properties and for testing of optical waveguides. The technique has not been satisfactorily developed as a permanent means for surface-coupling to integrated optical waveguides. This is due to several factors including, for example: (i) the requirement that the prism have an index of refraction equal to or greater than that of the integrated optical waveguide, which is challenging for silicon photonics in particular; (ii) the inability to produce compact and precise prisms in a cost effective manner; (iii) the precise mechanical alignment required to mount the prisms to the waveguide coupling region; (iv) the need to control the mode-shape and incident angle of the light beam entering the prism and controlling the interaction length between the prism and the waveguide; and (v) the possibility of damaging the waveguides due to the close proximity required between the waveguides and the prism. In part for these reasons, limited work has been reported on prism-coupling PLC waveguide applications for other than testing purposes.

### SUMMARY

In accordance with embodiments, provided are electronic device packages. The packages include: a sealed enclosure; an electronic device disposed in the sealed enclosure; and a conductive feedthrough allowing an electrical signal to pass into and/or out of the sealed enclosure; wherein the sealed enclosure includes: a first substrate having a surface on which first and second conductor segments are disposed, and an electrically discontinuous region on the surface between the first and second conductor segments; and a spacer circumscribing the electronic device, the spacer including the conductive feedthrough. The conductive feedthrough electrically connects the first and second conductor segments.

In accordance with embodiments, provided are methods of forming an electronic device package including a sealed enclosure, an electronic device in the sealed enclosure, and a conductive feedthrough allowing an electrical signal to pass into and/or out of the sealed enclosure. The method includes: (a) providing a first substrate having a surface; (b) forming first and second conductor segments on the first substrate surface, the first and second conductor segments having an electrically discontinuous region on the surface therebetween; (c) forming a spacer comprising a conductive feedthrough; and (d) bonding the spacer to the surface of the first substrate. The spacer circumscribes an electronic device and the conductive feedthrough electrically connects the first and second conductor segments.

In accordance with embodiments, provided are optoelectronic device packages. The packages include: a first substrate having a first surface and a second surface opposite the first surface; a lid over the first surface forming an enclosed volume between the lid and the first surface; an optoelectronic device in the enclosed volume; and one or more wick stops in the first substrate and/or the lid for controlling the flow of metal solder during formation of the optoelectronic device package.

In accordance with embodiments, the package may include a metal sealing ring surrounding the enclosed volume and through which the lid is attached to the substrate, wherein the one or more wick stops comprises a groove formed in the lid adjacent and external to, or adjacent and internal to, the metal sealing ring. Further, the one or more wick stops may comprise a groove formed in the base substrate and/or lid, wherein the groove contains residual solder remaining after formation of the optoelectronic device package. The optoelectronic device package can be a wafer-level package, comprising a substrate having a plurality of die, wherein each die comprises an optoelectronic device package as described herein.

In accordance with embodiments, an optoelectronic assembly is provided. The optoelectronic assembly comprises a planar lightwave circuit chip, and an optoelectronic device package such as described herein optically coupled to a waveguide of the planar lightwave circuit chip.

In accordance with embodiments, an optoelectronic assembly is provided. The optoelectronic assembly comprising a photonic integrated circuit chip comprising a planar lightwave circuit and electronic functionality; and an optoelectronic device package as described herein optically coupled to a waveguide of the planar lightwave circuit.

In accordance with embodiments, provided are optoelectronic device packages. The packages include: a first substrate having a first surface and a second surface opposite the first surface; a lid over the first surface forming an enclosed volume between the lid and the first surface; an optical source in the enclosed volume; a second substrate facing the second surface, the second substrate having an opening; and an optical isolator disposed in the opening. The optoelectronic device package has an optical path that passes through the first substrate and the optical isolator.

In accordance with embodiments, the first substrate and the lid may be formed of single-crystal-silicon. A turning mirror may be provided in the enclosed volume for reflecting light from the optical source through the first substrate. The turning mirror may comprise a metal layer formed on a surface of the lid. A ball lens may be provided in the enclosed volume between the optical source and the turning mirror. The enclosed volume in which the optical source is disposed may be hermetically sealed. The optical path through the first substrate may be at a normal or a non-normal angle. The optoelectronic device package may be formed on a wafer-level in which a substrate having a plurality of die is provided, wherein each the die comprises an optoelectronic device package as described herein.

In accordance with embodiments, provided is a prism-coupled optical assembly. The optical assembly includes: a first substrate comprising a prism for coupling light into an integrated optical waveguide; an optical component on and/or in the first substrate; and a second substrate comprising an integrated optical waveguide optically coupled to the optical component and prism, wherein the first substrate is attached to the second substrate and an optical path extends through the first substrate.

In accordance with embodiments, a prism-coupled optical assembly is provided. The optical assembly comprises: a base substrate, a lid, an enclosed volume between the base substrate and lid, a prism for coupling light into an integrated optical waveguide, and an optical component; and a planar lightwave circuit substrate comprising an integrated optical waveguide optically coupled to the optical component and prism, wherein the optical device package is attached to the planar lightwave circuit substrate and an optical path extends through the base substrate. In accordance with embodiments, the prism may be formed monolithically with the base substrate and/or the lid.

In accordance with embodiments, a method of forming a prism-coupled optical assembly is provided. The method involves providing a first substrate comprising a prism for coupling light into an integrated optical waveguide; providing an optical component on and/or in the first substrate; and attaching a second substrate comprising an integrated optical waveguide to the first substrate to optically couple the waveguide with the optical component and prism, wherein an optical path extends through the first substrate.

In various other aspects of the prism-coupled optical assemblies and methods of formation, the optical component may be an active device, such as an electro-optical or optoelectronic device, or a passive device, such as a lens, an optical fiber or other optical waveguide such as an integrated optical waveguide. The lens may be attached to a sloped surface formed in the first substrate, the sloped surface allowing for attachment of the lens at any selected height along the sloped surface. The prism may be monolithic to the first substrate. The first substrate may be formed in part or whole of single-crystal-silicon, and may comprise an off-axis cut <100> or <110> single-crystal-silicon. The second substrate may comprise a planar lightwave circuit comprising a plurality of integrated optical waveguides optically coupled to the optical component and prism. A lid may be provided on the first surface to form a sealed volume which hermetically encloses the optical device. An optical isolator may be mounted on the first substrate. The first substrate and/or the second substrate may include a plurality of spacers providing a gap spacing therebetween. An optical material may be disposed between the first substrate and the second substrate, the optical material having an index of refraction less than that of the first substrate and the integrated optical waveguide.

### DRAWINGS

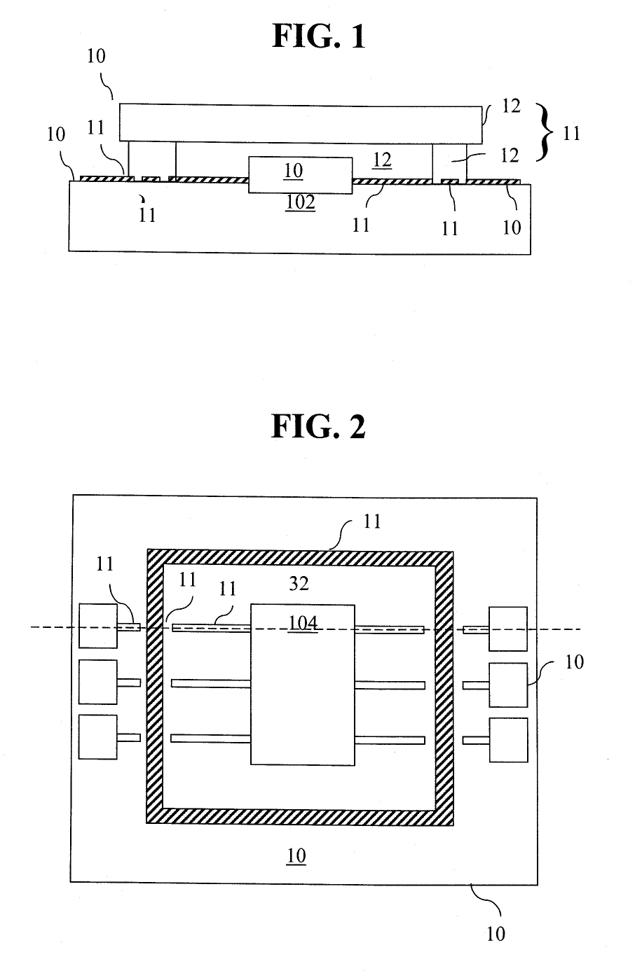

Example FIG. 1 illustrates a cross-sectional view of an electronic device package in accordance with embodiments.

Example FIG. 2 illustrates a top-down view of the base substrate shown in FIG. 1.

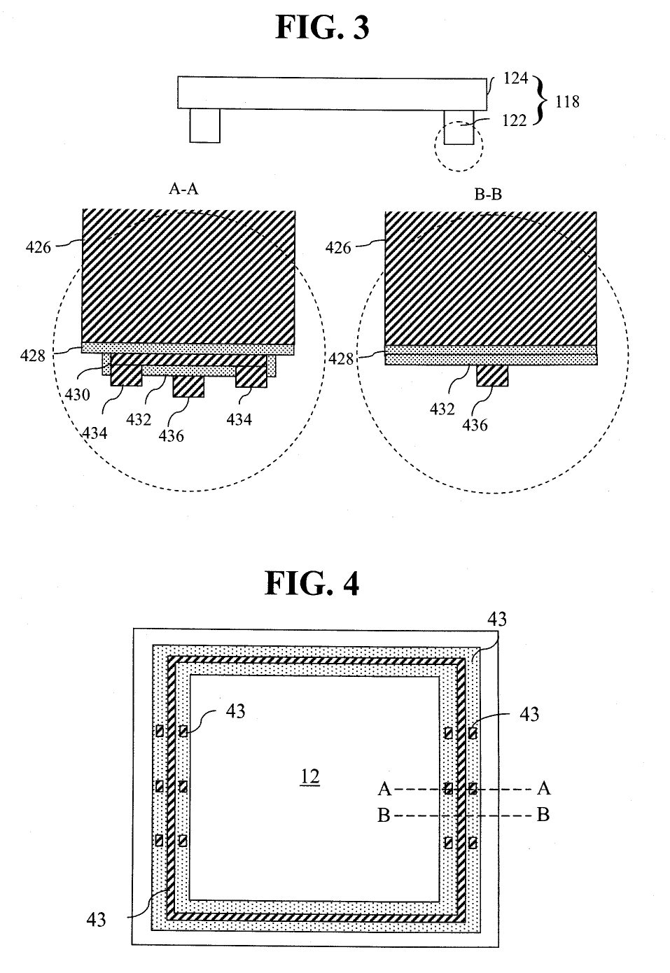

Example FIG. 3 illustrates magnified cross-sectional views of the spacer shown in FIG. 1.

Example FIG. 4 illustrates a bottom-up view of the lid shown in FIG. 1.

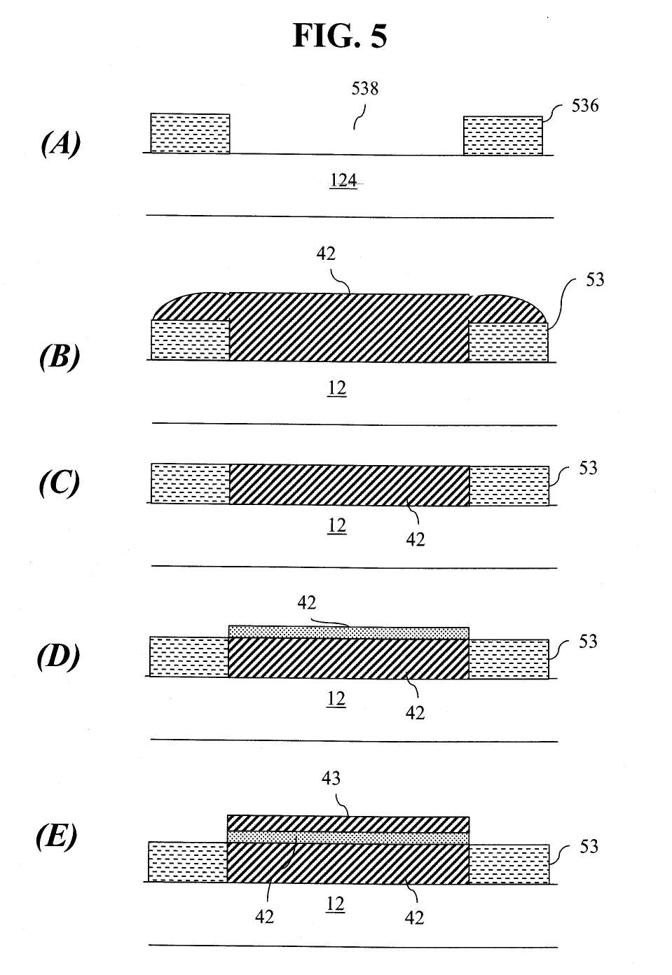

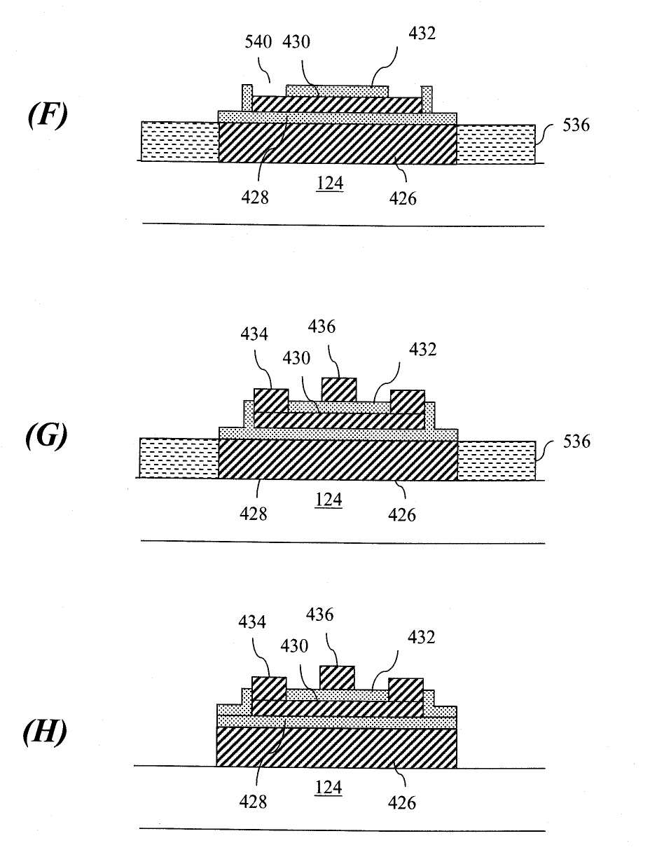

Example FIGS. 5A-H illustrate a partial cross-section of the lid shown in FIGS. 1, 3 and 4 at various stages of formation thereof.

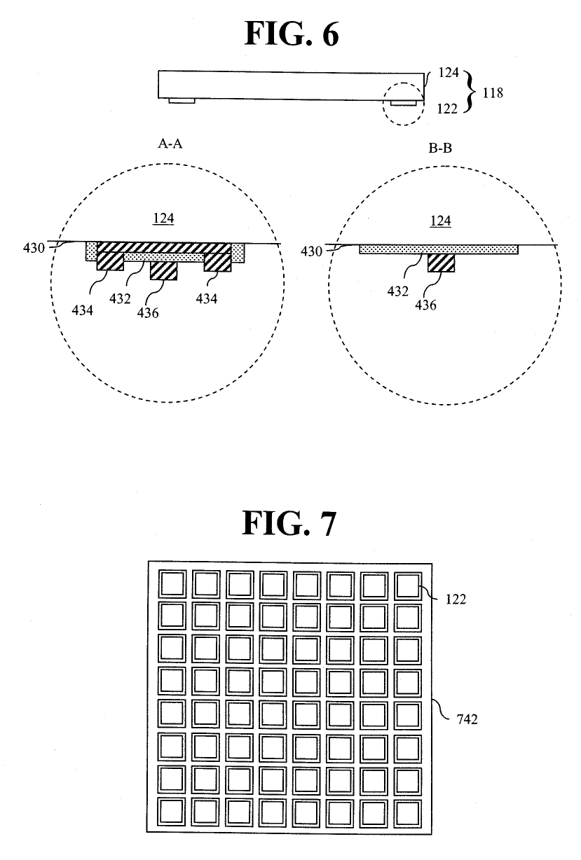

Example FIG. 6 illustrates magnified partial cross-sectional views of a second exemplary spacer in accordance with embodiments.

Example FIG. 7 illustrates a spacer grid in accordance with embodiments.

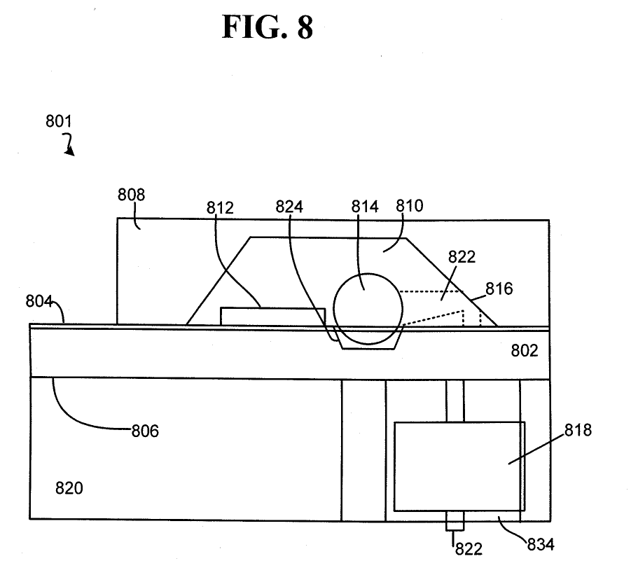

Example FIG. 8 illustrates a cross-sectional view of an optoelectronic device package in accordance with embodiments.

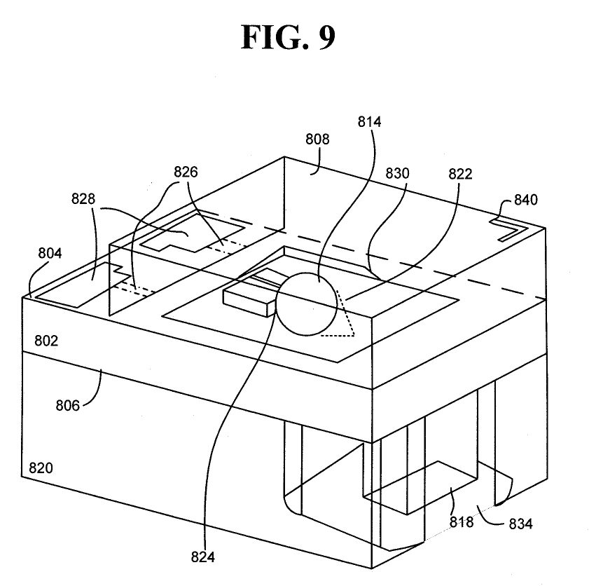

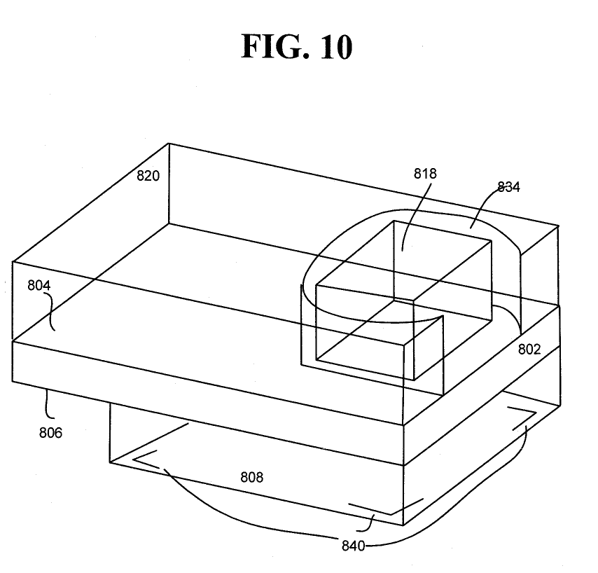

Example FIG. 9 illustrates a top isometric front view of the optoelectronic device package shown in example FIG. 8.

Example FIG. 10 illustrates a bottom isometric front view of the optoelectronic device package shown in example FIG. 8.

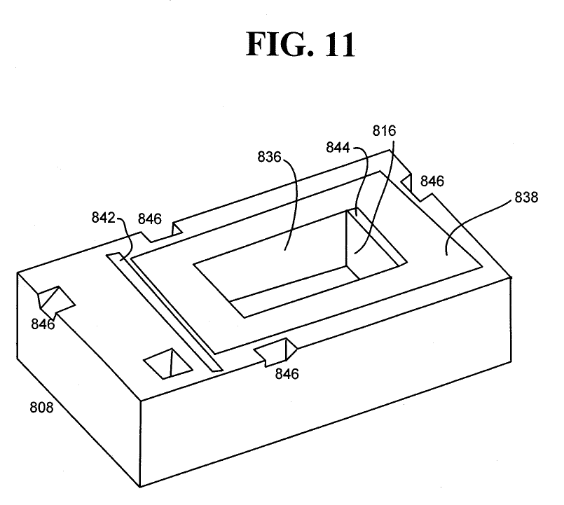

Example FIG. 11 illustrates an isometric bottom view of an exemplary package lid of the optoelectronic device package shown in example FIG. 8.

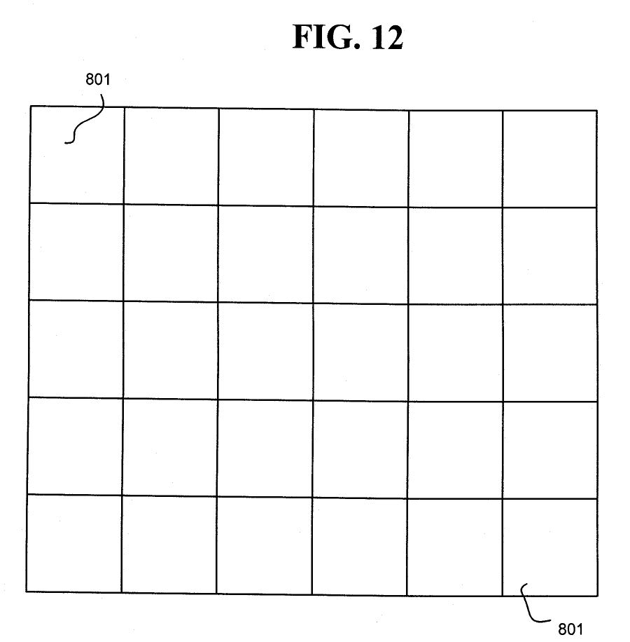

Example FIG. 12 illustrates a top view of an array of the optoelectronic device packages shown in example FIG. 8 formed on a grid-level, in accordance with embodiments.

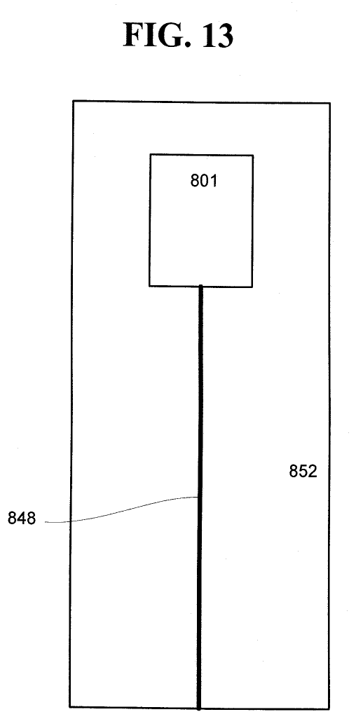

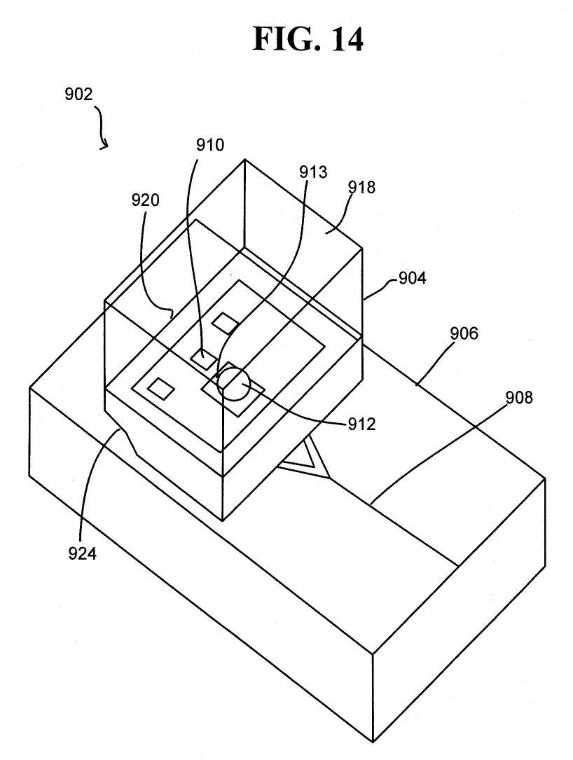

Example FIG. 13 illustrates an optoelectronic package mounted on and coupled to a planar lightwave circuit/photonic integrated circuit, in accordance with embodiments.

Example FIG. 14 is a perspective view of an exemplary prism-coupled optical assembly in accordance with embodiments.

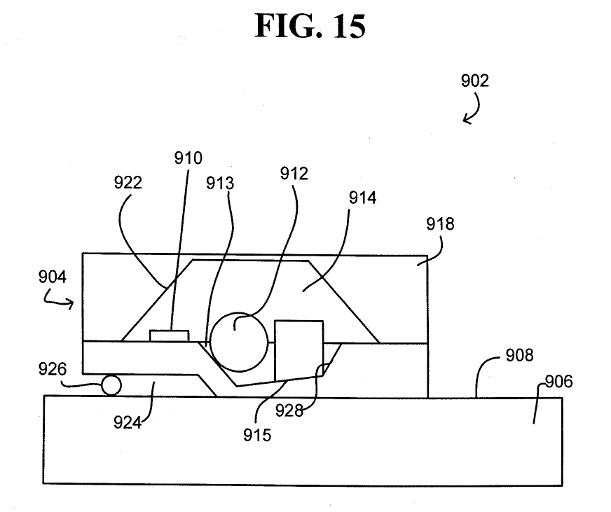

Example FIG. 15 is a cross-sectional view of the exemplary prism-coupled optical assembly shown in example FIG. 14.

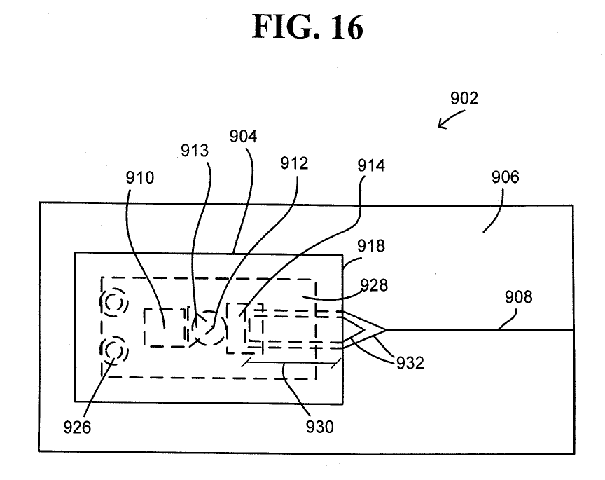

Example FIG. 16 is a top-down view of the exemplary prism-coupled optical assembly of example FIG. 14.

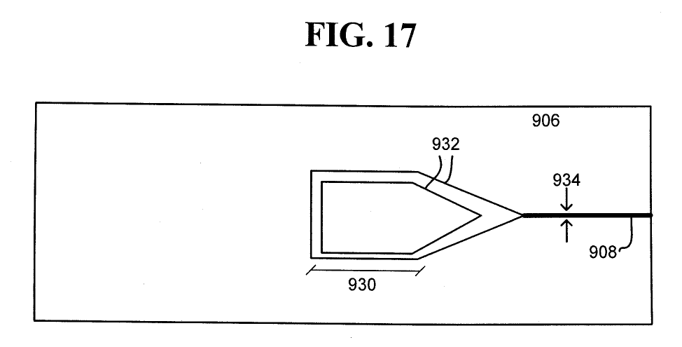

Example FIG. 17 is a top-down view of the PLC substrate with integrated optical waveguide shown in example FIG. 14.

### DESCRIPTION

As used herein, the terms “a” and “an” mean one or more; “microstructure” refers to structures formed by microfabrication or nanofabrication processes, typically but not necessarily on a wafer-level; and “wafer-level” refers to processes taking place with any substrate from which a plurality of die is formed including, for example, a complete wafer or portion thereof if multiple die are formed from the same substrate or substrate portion.

Embodiments relate to an improved structure and technique for providing an electrical feedthrough in an electronic device package. A conductive path is provided in a spacer separating the package base substrate and lid. The conductive path is electrically isolated from the region of the spacer which forms a seal with the base substrate. This makes possible the use of a metal-metal hermetic seal between the base substrate and lid.

The exemplary embodiments are described herein in the context of a MEMS device. Such a structure finds application, for example, in accelerometers, gyroscopes and digital light processors. Because the techniques can be applied to make hermetic lids from sheets or wafers of optical quality glasses and other materials having the desired transparency to the wavelengths of operation without causing damage to their optical surfaces or surface coatings, embodiments are particularly well-suited to optical device applications where a large optical window is required. Such applications include, for example, micro-bolometer arrays, focal plane arrays, moving micromirror arrays, phase modulator arrays and microchannel plate arrays. It should be clear, however, that the technology is in no way limited to the exemplary devices but can be applied to any type of electronic device having sensitivity to environmental conditions, for example, optoelectronic devices such as lasers and photodetectors, ICs, RF devices such as bulk acoustic wave devices, vacuum microelectronic devices, polymer-based microelectronics such as organic light emitting diodes (OLEDs) and polymer-based electro-optic materials. The packages find particular use where bulk or surface micromachining is used to form an electronic device which uses a controlled atmosphere or evacuated environment for operation. The term “microstructure” as used herein refers to structures formed by microfabrication or nanofabrication processes, typically but not necessarily on a wafer-level.

Example FIG. 1 shows a cross-sectional view of an exemplary electronic device package in accordance with embodiments. The device package 100 includes a base substrate 102 having an electronic device 104 mounted to or formed on or in an upper surface 106 thereof. The base substrate 102 can be formed of any material suitable for use in hermetic packaging of electronic devices. The base substrate material can be, for example, a semiconductor such as silicon, silicon-on-insulator, silicon-germanium, ceramics, glasses, and metals such as copper. In the case of a MEMS device, a semiconductor substrate such as single crystal silicon or silicon-on-insulator is typical. Depending on this material, the base substrate can include one or more dielectric layer formed on all or any portion thereof for electrical isolation or other purposes. Typical dielectric layers include, for example, low stress silicon nitrides, doped and undoped silicon oxides including spin-on-glasses, and silicon oxynitrides. Any such dielectric layers may be formed by known techniques such as plasma or low pressure chemical vapor deposition (PECVD or LPCVD), spin-coating, anodization or thermal oxidation. The base substrate can be of a dimension allowing for formation of a single component or a plurality of identical components as multiple die. Typically, the base substrate will be in the form of a wafer having multiple die on the wafer. As used herein, the term “wafer” shall mean any substrate from which a plurality of die is formed.

The electronic device 104 can be formed from, in and/or on the base substrate 102, for example, in the case of typical MEMS devices such as an optical MEMS device as shown in the exemplary package, or can be mounted, for example, as a prefabricated device, to the base substrate. The former type of device is typically formed early in the process while prefabricated devices would typically be mounted to the base substrate surface just prior to bonding the lid to the base substrate. Methods of forming electronic devices are well known to those skilled in the art and will not be further discussed.

A metal conductor pattern is formed on the upper surface 106 of the base substrate for providing electrical connectivity to the electronic device 104. Example FIG. 2 illustrates a top-down view of the base substrate 102. The dashed line represents the plane at which the cross-section of example FIG. 1 is taken. The metal conductor pattern includes one or more bonding pads 108 which are external to the hermetic cavity described below, and one or more first and second conductor line segments 110, 112 between respective bonding pads and the electronic device. In place of the bonding pads 108, conductive vias (not shown) can be employed if it desired to route the conductor to the opposite side of the base substrate. While three conductors each on two sides of the base substrate are illustrated, it should be clear that any number of conductors extending on any number of sides of the electronic device can be employed depending on the requirements of the electronic device. The first and second conductor line segments are discontinuous, being separated by a gap 114. In certain cases, one or more of the conductors can be continuous where it is desired to tie the conductor electrically to the metal seal ring 116 described below. This can be done, for example to provide a ground plane for RF devices or to provide a bias or modulation, for example, in RF devices where the metal seal ring also serves as part of an antenna.

The length of the gap 114 will depend on the dimensions of other features of the structure, but is typically, from 10 to 500 microns. The metal conductor pattern can be formed from a suitable metal material, for example, aluminum, copper, nickel, nickel-palladium, aluminum, chromium, gold, titanium, alloys thereof, or other combinations thereof, for example, multiple layers of such materials. The metal conductor pattern may be formed by conventional metallization techniques such as electroless or electrolytic plating, evaporation, sputtering or CVD, and photolithography and etching techniques in the case of non-selective, blanket metallization.

A metal seal ring 116 is formed on the substrate within gap 114 and circumscribing the electronic device 104. In the illustrated structure, the seal ring is rectangular in cross-section. It should be clear that other geometries such as a circular or ovular ring can be employed with the same effect. The seal ring lies between and does not contact the first or second conductor line segments 110, 112. This electrical isolation is to avoid shorting of the device. The seal ring may be formed of a solderable material which provides a hermetic seal when bonded to the package lid as described below, and can be formed at the same time using the same material(s) and techniques as the metal conductor pattern. By employing a metal material for the seal ring, the ring's width can be significantly reduced in comparison with the use of a glass frit ring. This can allow for a greater number of packages to be formed on a single substrate. In the case where the seal ring is formed at the same time as the metal conductors and is formed from aluminum, the ring can be treated by post processing that includes electroless nickel and immersion gold to provide a more readily solderable surface. Alternatively, processes that bond directly to aluminum can be used.

A lid 118 is attached to the base substrate upper surface 106 to form a hermetically enclosed volume 120 in which the electronic device 104 is contained. A spacer 122 may form a sidewall portion of the lid, and a lid substrate 124 forms a ceiling portion. The spacer gives height to the lid, providing clearance above the electronic device for the ceiling portion. The spacer is bonded to the metal seal ring 116 on the base substrate to form a hermetic seal and sealed volume. In addition to forming a hermetic seal with the substrate, the spacer acts as an electrical jumper, providing a conductive path between the first and second conductor line segments 110, 112, allowing for electrical connection between the bonding pads 108 and the electronic device. The spacer height will depend, for example, on any protrusion of the electronic device or associated components above the device wafer surface, the desired volume for the hermetic cavity, the minimum vacuum or gas volume to set the maximum rate of pressure change per unit time for a given maximum allowable leak, and the specific type of electronic device in the cavity. While the height can vary widely, a typical spacer height is from 5 to 250 microns and a typical width is from 30 to 500 microns.

The lid substrate is formed of a material which is selected based on desired characteristics of the package, for example, gas permeability, optical properties and coefficient of thermal expansion (CTE). In the case of an optoelectronic or optical MEMS device which sends and/or receives optical signal through the ceiling portion, it is generally desired that the material is optically transparent at the desired wavelengths. Suitable materials for the lid substrate in such as case include, for example, glasses such as Schott BK-7 (Schott North America, Inc., Elmsford, N.Y. USA), Pyrex (Corning Inc., Corning, N.Y. USA) and single crystal silicon. The lid substrate can be coated on one or both surfaces with one or more antireflective or other optical coatings. In addition other materials can be deposited or deposited and patterned on the lid such as getters such as non-evaporable getters. Where optical transparency is not required, the transparent or non-transparent such as described above with reference to the base substrate can be used for the lid substrate. Alternatively, etched, stamped or otherwise-formed metals can serve as the lid. An exemplary metal for use in the lid is tantalum, which has a CTE close to that of silicon.

The lid ceiling portion is of a size sufficient to enclose the desired portion of the package. A typical length and width for a rectangular ceiling portion is, for example, on the order of from about 1 to about 50 millimeters (mm). As with the base substrate, the lid substrate can be in wafer-form, making possible the simultaneous manufacture of multiple lids. The resulting base substrate wafers and lid wafers can be assembled together on the wafer-level, allowing for a completely wafer-level manufacturing process. Lid wafers can take the form, for example, planar sheets such as disks or rectangles. The lid wafers can be pre-machined to allow electrical contact to the substrate wafer without added machining after dicing. This can allow wafer-level testing before singulation of the individual packages while minimizing the mechanical stress and cost of post-machining operations to create such openings after the sealing operation. Such pre-machined lid wafers may be formed by known methods such as hot-molding, etching, and/or abrasive blasting.

Example FIG. 3 illustrates magnified cross-sectional views of an exemplary spacer and example FIG. 4 illustrates a bottom-up view of the lid shown in example FIG. 1. The magnified views are of portions of the spacer to be bonded to the base substrate 102 as cross-sections taken along the dashed lines A-A and B-B of example FIG. 4. The spacer includes a base 426 in contact with the lid substrate 124. As illustrated, the spacer base 426 is typically in the form of a ring having a shape complementary to that of the seal ring 116. In the exemplified structure, the base is constructed of a metal, for example, nickel, copper, copper-tungsten or aluminum. Other materials such as semiconductors, for example, silicon or silicon-germanium, dielectric materials, for example, doped or undoped silicon oxides, low stress silicon nitrides or silicon oxynitrides, and combinations thereof can alternatively or additionally be used. The spacer base can be formed of a single layer or multiple layers of such materials. The choice of materials will depend, for example, on factors such as gas permeability, desired deposition rate and CTE. The spacer base can optionally be etched into or formed directly from the material of the lid wafer. In cases where the height inside the package can be minimal, for example, where the electronic device is formed from the base substrate and does not have a significant height above the base substrate upper surface, the spacer base and other layers of the exemplary spacer may not be required. In such a case, sufficient clearance above the device wafer surface might be achieved directly by other layers of the spacer as described below with reference to example FIG. 6.

In the case a metal is used in forming the spacer base 426, as in the exemplified structure, a first dielectric layer 428 is disposed over the surface of the base to electrically isolate the spacer base from the electrically conductive structures thereon. The first dielectric layer 428 it typically coextensive with the base, but may be left out where the spacer base itself is formed from a dielectric material. The material and thickness for this and other dielectric layers will depend on factors such as gas permeability, breakdown voltage, capacitive coupling and other electrical requirements, CTE, and stress and adhesion requirements. Suitable materials include, for example, an oxide of the underlying metal which can be formed by anodization, a PECVD material such as silicon nitride, silicon oxide, silicon carbide or silicon oxynitride, or a sputtered glass such as Pyrex glass. The thickness of the first dielectric layer can be, for example, from tens of nanometers (nm) to tens or hundreds of microns.

The spacer further includes a feedthrough conductive trace 430 over the first dielectric layer 428, and feedthrough contacts 434 over and in contact with the feedthrough conductive trace at an end portion of the spacer which is to contact the base substrate. The feedthrough conductive trace is typically of similar width to the first and second conductor line segments 110, 112. The length generally corresponds to the gap 114 between the first and second conductor line segments. The thickness of the feedthrough conductive trace will depend, for example, on the trace material and the current carrying requirements. The feedthrough conductive trace can, for example, include a multilayer stack including a 5 to 50 nanometer adhesion layer such as titanium or chromium, with one or more metal layers such as titanium-tungsten, nickel or platinum, gold or a combination of these layers that form the bulk of the layer on the adhesion layer. Suitable metal stacks are well known in the art of thin film microelectronics and semiconductor processing. The metal feedthrough layer can further include a metal cap layer and/or an oxidation barrier film, for example, of nickel-palladium, gold or silver.

The number, geometry and placement of the feedthrough contacts 434 are selected to allow electrical connection of the first and second conductor line segments 110, 112. Depending on the ability to pattern the feedthrough contacts, the use of bonding pads larger than the width of the conductor segments 112, 114 may be used at the ends of the segments which define the gap 114. In the exemplified structure, two feedthrough contacts are provided for each metal conductor, one contact for the gap on each side of the seal ring 116 on the base substrate 102. A plurality of such contacts on each side of the seal ring can be employed if desired. Suitable materials for the feedthrough contacts include metals, for example, solders such as gold-tin, tin, indium, tin-silver, and many other solder systems that are known in the art. Such solders are typically chosen for their ability to be reflowed without the need for a liquid flux and to provide a reliable seal and electrical contact. These solders can be deposited by one or more vapor deposition steps, electroplating, screen printing, or contact with a molten solder pool.

During processing, the feedthrough contacts typically reflow, making an electrically continuous circuit between first and second conductor line segments 110 and 112, while forming a hermetic seal around the circumference of the metal seal ring 116. A second dielectric layer 432 is disposed over the surface of the feedthrough conductive trace 430 except for those regions occupied by the feedthrough contacts. Suitable dielectric materials for the second dielectric layer 432 include those described above with respect to the first dielectric layer 428, as well as materials such as benzocyclobutene resins, epoxies and other resins. This material choice is based, for example, on the material's level of hermeticity to water vapor, oxygen, and helium. Low leak rates for helium, however, may call for the use of only inorganic materials throughout the cross-section of the seal.

A metal seal ring 436 is disposed over the second dielectric layer in a complementary geometry to that of the seal ring 116 on the base substrate. Seal ring 436 is electrically isolated from the feedthrough contacts and the feedthrough conductive trace, and forms a hermetic seal when bonded to the seal ring 116 of the base substrate in the final package. The materials described above with respect to the feedthrough contacts are applicable to the seal ring 436. Typically, the feedthrough contacts and seal ring 436 are formed of the same material and at the same time. In the assembled package, the spacer effectively provides a jumper circuit for electrically connecting the first and second conductor line segments 110, 112. The conductive path moves out-of-plane from the conductors on the base substrate first surface to a second plane in the spacer offset from the conductor plane, and then back down to the conductor plane. The dimension for this out-of-plane motion will depend, for example, on dielectric and metal layer thicknesses in the spacer, but are typically from several tens of nanometers to tens of microns.

The electronic device packages can be provided with various structures for controlling the collapse and flow of solder during fabrication of the package. These structures can be disposed on the base and/or lid substrate. For example, an additional dielectric layer can be patterned on one or both sides of the metal seal ring 436, the dielectric layer following the ring's contour in whole or in part. The thickness of such layer can be chosen to control the height of the bond line which feedthrough contacts 434 and seal ring 436 produce after reflow. In addition, this dielectric can also be placed in whole or in part around the feedthrough contacts 434. Polymeric materials can be used to control solder collapse while still allowing an organic-free interior if they are disposed only in regions outside the circumference of the seal ring 436. For example, PECVD oxides or nitrides, polyimides, photosensitive-benzocyclobutene (Photo-BCB) resins such as those sold under the tradename Cyclotene (Dow Chemical Co.), photoepoxies such as SU-8 resist (MicroChem Corp., Newton, Mass.) and other spin-coatable materials that can be photopatterned can be used outside of seal ring 436 if outgassing is a concern.

Other structures which can be used to control solder reflow include, for example, solder dams and wick stop layers on the base substrate 102, as well as shaped bond pads at the ends of the first and second conductor line segments 110, 112. Wick stops can prevent the flow of the solder on the first and second conductor line segments. They can be made using a patterned dielectric over the regions of the metal trace that are to be protected from solder flow as is done in semiconductor metal passivations, or they can be made by etching back a solder-wettable top metal that comprises the first and second conductor line segments. This can be done over the entire length of the conductor segments except where solder attachment is desired. Alternatively, the wettable top metal on the base substrate 102 can be etched back over a very short distance from the first and second conductor line segments to prevent flow of the solder. This is typically done when the top wettable metal also is a primary current conductor. For example, when the top metal is a stack including an adhesion layer such as chromium or titanium, a diffusion barrier such as nickel, and a cap metal such as gold, the cap metal can be removed from the first and second conductor line segments over a short distance, for example, from 10 to 100 microns, adjacent the region of solder attach for feedthrough contacts 434 on the first and second conductor line segments, since the solder can be prevented from wicking onto the nickel. This allows gold to remain as primary conductor without introducing significant resistance in the regions where it is etched back. These techniques may optionally be used in whole or part, depending on the materials and the process challenges during bonding.

A spacer formation process, in accordance with embodiments, will now be described with reference to example FIGS. 5A-H which illustrate a spacer in partial cross-section, taken along line A-A of example FIG. 4, at various stages of formation. Suitable materials and thicknesses for the various layers making up the structures are described above and are applicable to the following description. With reference to example FIG. 5A, a layer of a sacrificial photosensitive material 536 such as a photoresist is coated over a lid substrate 124 as described above, and is exposed and developed to form a ring-shaped channel 538 complementary in geometry but greater in width than that of the seal ring 116 on the base substrate 102. Typically, the channel is greater in width than the regions for attach at the corresponding ends of the first and second conductor line segments 110, 112. Conventional photolithography steps and materials can be used for this purpose. The sacrificial photosensitive material can be, for example, one or more layers of a photoresist, for example, a negative photoresist such as Shipley BPR™ 100 photoresist (Rohm and Haas Electronic Materials LLC, Marlborough, Mass. USA), or a lift-off resist. The thickness of the sacrificial photosensitive material will depend on the dimensions of the structures being fabricated, but is typically from about 10 to about 250 microns. A 100 micron thick negative photoresist layer is coated, followed by exposure and development in an aqueous developer such as TMAH, KOH or NaOH to form a 300 micron wide channel having a length of about 10 mm and a width of about 10 mm.

A base layer 426 is formed in the channel 538 as shown in example FIG. 5B. The base layer can be formed by known techniques, for example, electroless or electrolytic plating, evaporation, sputtering, CVD, in the case of a metal, or CVD or oxidation in the case of a dielectric material. The base layer can, for example, be formed by vapor deposition of a thin seed layer of chromium/nickel/gold to provide adhesion and electrical connection, followed by electroplating of copper. While the illustrated structure shows the base layer at a height greater than that of the sacrificial material 536, it may be desired to form the base layer with a thickness less than that of the sacrificial material. The surface can be planarized, for example, using chemical mechanical planarization (CMP) or other lapping or polishing technique, as shown in example FIG. 5C. In the exemplary method, the base layer is formed in the bottom of the channel 538 by coating about 50 nm of chromium, about 100 nm of nickel and about 100 nm of gold to produce an about 250 nm thick metal seed layer, followed by blanket electroplating copper to a thickness of greater than about 100 microns over the seed layer. The resulting surface is planarized through the copper and seed layers that protrude or are layered above the surface of the sacrificial material 536 down to the bare surface of the sacrificial material. A selective stop on the sacrificial material can be readily accomplished by CMP using techniques know in the art. Post-treatment with electroless nickel can be conducted to provide added adhesion to subsequent layer depositions. Alternative methods include, for example: polishing to the copper and removing the seed layer on the sacrificial material chemically; or providing a seed layer under the sacrificial material, plating the structure into the sacrificial material mold, optionally planarizing with CMP, and later stripping the seed layer after the sacrificial material is stripped.

Where a metal or other conductive material is used for base layer 426, a first dielectric layer 428 is next formed as shown in example FIG. 5D, typically by blanket deposition over the entire surface of the base material 426, sacrificial material 536 and exposed portions of lid substrate 124, followed by photolithographic patterning and etching. Depending on the film formation technique, the layer can be selectively deposited over a portion of the structure. The first dielectric layer can be formed, for example, using CVD, such as LPCVD or PECVD, spin-coating, evaporation, sputtering, thermal oxidation, anodization or other techniques known in the art of depositing thin dielectric layers. In the exemplary method, the first dielectric layer is an about 100nm thick blanket-deposited PECVD silicon oxide or nitride layer, deposited at a typical temperature between about 100 and about 300° C.

As shown in example FIG. 5E, the feedthrough conductive trace 430 is next formed over the first dielectric layer 428. Layer 430 can be formed by known techniques for metal film formation such as those described above with respect to the base layer 426. In the case of blanket deposition, the metal layer can be photolithographically patterned and etched to form the conductive trace. In the exemplary method, the feedthrough conductive trace is formed by sputter-depositing a 50 nm chromium adhesion layer, a 100 nm thick nickel layer and a 100 nm thick gold cap metal, followed by photolithographic patterning and wet etching to form the conductive trace.

The second dielectric layer 432 is next coated over the feedthrough conductive trace 430 and patterned to provide openings 540 exposing the underlying feedthrough conductive trace 430 as shown in example FIG. 5F. Layer 432 can be formed by known techniques for dielectric film formation such as those described above with respect to the first dielectric layer 428, followed by photolithographic patterning and etching. Optionally, a photoimageable dielectric material can be used in which that portion of the layer which is not removed remains as a permanent structure in the formed package. Suitable materials include, for example, photosensitive-benzocyclobutene (Photo-BCB) resins such as those sold under the tradename Cyclotene (Dow Chemical Co.), photoepoxies such as SU-8 resist (MicroChem Corp., Newton, Mass.), or a negative acting photoresist which is not attacked by the sacrificial material removal process and otherwise meets level of hermeticity, CTE and other requirements of the package. Polymeric materials may not be desired where low leak rates to helium or hard vacuum sealing are required. The second dielectric layer is an about 250 nm thick blanket-deposited layer of PECVD silicon oxynitride, and is followed by photolithographic patterning and etching to form 50 micron diameter circular or square openings which expose underlying regions of the conductive layer 430.

The structure is next metallized to form feedthrough contacts 434 and metal seal ring 436 as shown in example FIG. 5G. The metallization can be a selective process, for example by formation and patterning of a metal seed layer followed by electroplating, or selective CVD. Alternatively, the process can include blanket deposition followed by photolithographic patterning and etching. In the exemplary method, the feedthrough contacts and metal seal ring are formed by coating and patterning an about 250 nm thick chromium/nickel/gold metal seed layer as previously described, followed by lift-off deposition of gold-tin to a thickness of 10 microns. In an alternative exemplary process, the solder can be plated tin and optionally treated in a fluorine-containing plasma to provide an oxide barrier. Solder thickness can range, for example, from several microns to many tens of microns.

Next, the sacrificial material 536 is removed from the structure with a suitable stripping solution, for example, an aqueous sodium hydroxide solution or a good solvent such as N-methylpyrilidone (NMP), N,N-dimethyl formamide, acetone, 2-butanone or other solvents which swell or dissolve the polymer, with the resulting structure being shown in example FIG. 5H.

The lid and base substrate are next brought into contact and aligned with each other such that the metal seal ring 116 of the base substrate is in alignment with the metal seal ring 436 of the spacer, and the feedthrough contacts 434 are aligned with the gaps between the first and second conductor line segments on either side of the metal seal ring 116. The package is heated to a temperature and for a time to effect bonding between the metal seal rings 116, 436 on the base and lid, and reflowing of the feedthrough contacts 434 to fill in the gaps between the first and second conductor line segments. In this way, a hermetic seal between the lid and base is formed, and the first and second conductor line segments become electrically connected.

While the spacer structure in the above-described exemplary method is formed as part of the lid, it should be understood that the spacer can be formed on the base substrate which is then joined to the lid. The spacer can, alternatively, be formed as a part separate from the base substrate and lid which is later joined to the lid, the base substrate or both the base substrate and the lid at the same time. Still further, fabrication of the spacer can initially be started as a separate part and completed after assembly to the base substrate or lid. Where the spacer is at least partially fabricated as a separate component, it can be formed from a sheet of metal, for example, a tantalum sheet, that is patterned and etched to form one or more frames that can be attached to the base substrate or lid substrate as a single unit. A structure is illustrated in example FIG. 7, which includes a metal sheet 642 from which a plurality of completed spacers 122 as described above are formed. In this way, the number of frames formed from the sheet can be made to correspond with the number of die on the base and lid substrate, making its use consistent with wafer-level processing. Precision etching of metal sheets and foils is well known in the art. Where silicon forms part of the package material, for example, as a base or lid substrate, use of tantalum sheet may be desirable as its CTE is well matched to that of silicon. One or more steps of forming the spacer described above, for example, applying and patterning dielectric, metal, solder and resist materials can be done to the metal sheet. In this case the grid can be bonded to the base and lid substrates, for example, with solder, by Si—O bonding or other bonding chemistry.

After bonding of the lid wafer to the base substrate wafer, the lids can be separated from one another by dicing the lid substrate to expose the contact pads. Alternatively the pads can be exposed where a preformed lid sheet or individual lids are used to cap the devices. In separating the lids, the bonding pads outside of the hermetic enclosure become exposed. As a result, the packages can advantageously be tested on the wafer-level prior to singulation. Wafer-level testing of the devices is simpler and a less time consuming technique than doing so for each singulated package. Finally, the packages may be singulated from the wafer-level into individual packages, for example, by dicing or other known techniques.

Embodiments relate to improved optoelectronic device packages, planar lightwave circuits and photonic integrated circuits, and their methods of manufacture. Embodiments provide improved optoelectronic device packages, planar lightwave circuits and photonic integrated circuits, in which problems associated with uncontrolled flow of solders can be minimized or eliminated. This is achieved by the use of one or more wick stops in the package base substrate and/or lid. In accordance with embodiments, the optoelectronic device packages allow for vertical coupling of optoelectronic devices into waveguides residing on or within a PLC or PIC chip in a highly reproducible, stable and simple manner and with a small form factor. Further, the device packages, in accordance with embodiments, allow for wafer-level assembly, thus decreasing cost relating to handling, processing and materials, and providing increased throughput. Device packages in accordance with embodiments advantageously are capable of producing an output beam with a precise focus at a desired location, typically adjacent or very close to the back surface of the package, at a well controlled angle and with very small aberrations, resulting in high levels of optical coupling efficiency.

Example FIGS. 8-11 illustrate various views of an optoelectronic device package microstructure 801 in accordance with embodiments. The exemplified device package includes a base substrate 802 having a front surface 804 and a back surface 806. A lid 808 is mounted to the base substrate front surface 4, enclosing a volume 810, typically a hermetic volume. A light source such as edge-emitting laser 812 and ball lens 814 are attached to the front surface 804 and disposed within the enclosed volume 810. Also in the enclosed volume is a turning mirror 816 which may be formed on an interior surface of the lid. An optical isolator 818 may be employed, in which case it can be provided in a spacer substrate 820 mounted to the back surface of the base substrate. In operation, a light beam 822 is emitted by the laser in a direction generally parallel to the front surface. The ball lens 814 collects and focuses or collimates the emitted light. The light beam is then reflected by the turning mirror and projected through the base substrate and the optical isolator.

The base substrate 802 may be formed of any material suitable for use in packaging of optoelectronic devices which is transparent to light of a wavelength or wavelengths characteristic of the optoelectronic device 812 in the package. Typical such materials include, for example, a single crystalline semiconductor material such as single-crystalline silicon, silicon-on-insulator, silicon-germanium substrate, or glasses such as Schott BK-7 (Schott North America, Inc., Elmsford, N.Y. USA) and Pyrex (Corning Inc., Corning, N.Y. USA). In the exemplary package, the base substrate is formed of single-crystalline-silicon. The base substrate can be coated on the front and/or back surfaces with one or more antireflective or other optical coatings. The base substrate can be of a dimension allowing for formation of a single package or, more typically, a plurality of identical packages as multiple die in a wafer-level process. Typically, the substrate will be in the form of a wafer having multiple die.

Depending on the substrate material, one or more dielectric layers may be provided on the front surface 804 and/or back surface 806 for providing electrical isolation between the base substrate and electrical structures such as conductors and electronic devices disposed thereon. Suitable dielectric layers include, for example, low stress silicon nitrides, doped and undoped silicon oxides, including spin-on-glasses, silicon oxynitrides, titanium dioxide and combinations thereof. The dielectric layers are typically formed by known techniques such as plasma enhanced CVD (PECVD), low pressure CVD (LPCVD), spin-coating or thermal oxidation. The thickness of the dielectric layer will depend on factors such as the particular material and subsequent process conditions. A typical thickness for the dielectric layer is from about 100 to about 250 nanometers (nm).

The base substrate 802 is processed to provide various surface features. For example, one or more pyramidal pit 824 can be formed in the front surface 804 to accommodate optical elements such as ball lens 814. Such a pit may be defined lithographically using wet etching, for example, wet anisotropic etching of a (100) silicon substrate front surface, resulting in a wet-etched pit having inclined sidewalls that are {111} crystallographic planes. Such a structure can be accurately formed, thus allowing for precise placement of the ball lens or other optical elements.

Additional surface features on the base substrate front surface, and optionally the back surface, include metal features. Such features include, for example, conductive traces 826 for providing electrical connectivity to the optoelectronic device and contact pads 828 for allowing electrical connectivity to the outside world. Suitable metal materials for these features are known in the art and include, for example, chromium (Cr), nickel (Ni), titanium (Ti), platinum (Pt), gold (Au) and combinations thereof, such as a stacked layer of Cr/Ni/Au, TiW/Au or Ti/Pt/Au. These metal structures may be deposited by known techniques, such as evaporation, sputtering, CVD, electro-chemical and electroless chemical plating of one or more metals, for example, using a seed process and patterned mask if desired. Plating may be especially useful for relatively thick layers, for example, thick gold-containing layers. Any combination of these techniques may be employed. The metal features may be patterned, for example, with a shadow mask, a conformal lift-off resist, a spray coated resist or a laminated patterned resist followed by chemical etching of the metal, among other methods known in the microelectronics art.

In the illustrated package, the traces 826 and contact pads 828 are formed on the front surface of the base substrate. Optionally, the conductive traces can be formed so as to extend through the base substrate from the front to back surface using conductive vias. In this case, the conductive vias would be connected to contact pads formed on the back surface of the base substrate. The contact pads on the back surface can, for example, be wire bonded, solder attached to a printed circuit board (PCB), solder attached to a flexible circuit, or solder attached to other electronic substrates including, for example, ceramic substrates.

Additional metal surface features which can be formed on the base substrate front surface include solder pads for bonding the optoelectronic device 812 and any other optoelectronic or electronic devices to the base substrate. The solder pads are connected to electrical traces 826 which are connected to the contact pads 828. Typical solder pad materials include, for example, Au—Sn eutectics, In or other alloys chosen for their melting points and mechanical and attach process properties. The solder pads can be formed and patterned by conventional techniques such as those described above with respect to other metal features.

A sealing ring 830 may be formed on the front surface for subsequent bonding of the lid 808 to the base substrate to allow for the formation of a hermetic seal between the lid and base substrate. A metal sealing ring that is complementary in geometry to the sealing surface of the lid is typically employed. In the case of a metal sealing ring and conductive traces which pass under the lid, the conductive traces must be electrically isolated from the ring metals. This can be accomplished, for example, with a dielectric cap layer, such as an oxide or nitride cap layer, over the trace metallization. The metal sealing ring may be formed of a metal stack comprising an adhesion layer, a diffusion barrier and a wettable metal layer. For example chrome and titanium are common adhesion layers, nickel, platinum and titanium-tungsten are common diffusion barriers, and gold is a common wettable metal. In addition, the sealing ring may include a solder, for example, about 80:20 Au—Sn of from about 3 to about 8 microns in thickness.

One or more wick stops may be provided in the base substrate for controlling the flow of metal solders at one or more locations in the package. For example, the sealing ring may be patterned in a manner to cause the metal solder to selectively flow in given regions, wicking more or less solder where desired during the lid attachment step. Such an arrangement can be useful, for example, if there are regions of transition or topology or higher surface roughness and a thicker metal solder layer is desired for the seal in that region, for example, when sealing over the conductive traces.

Additional exemplary surface features which may be formed on the base substrate include alignment fiducial marks to allow for accurate automated alignment and bonding of elements, such as the optoelectronic device, ball lens and lid, to the base substrate.

An optical element, such as ball lens 814, may be seated in the trapezoidal pit 824 for receiving the light beam 822. Typically, the ball lens seats in the pit by contacting the four sidewalls of the pit 820. The ball lens may be adhered to the pit using a suitable adhesive or bonding agent, such as a solderglass or a solder that will wet the lens. Solders may be deposited directly into the pit by evaporation or sputtering through a shadow mask, or may be deposited using solder balls, among other methods. Solder glass may similarly be deposited directly into the pit or may take the form of a glass preform. To prevent obscuration of the lower marginal ray emitted from the laser die 812, the light emitting edge of the laser die may desirably be placed adjacent to the pit 820, so that the lower marginal ray propagates downward into the pit to intercept the ball lens without striking any portion of the base substrate front surface. Optionally, the laser die may be spaced apart from the ball lens and a recessed clearance surface may be provided to permit the lower marginal ray to reach the ball lens unobstructed. The optical properties of the ball lens may be selected such that the focal point is at a desired position.

The optoelectronic device 812 is typically an optical source such as an edge-emitting laser but it is envisioned that a surface-emitting laser may alternatively be used with additional modification to the device package. Still further, optical detectors such as photodiodes are envisioned. The optoelectronic device can be bonded to the base substrate front surface by conventional techniques and materials, for example, bonding to a pre-formed solder pad (not shown) on the front surface, or use of epoxy or gold bump fusion bonding. The optoelectronic device may be flip-chip attached to the base substrate front surface to make electrical connection with the conductive traces. Optionally, the optoelectronic device 12 may be wedge-bonded, wire-bonded or a combination thereof. Although a single optoelectronic device is shown in the exemplary device package, it should be clear that multiple such devices, or additional other optoelectronic or electronic devices, may be included in the package and connected to the base substrate or lid.

The optical isolator 818 can be integrated into the package in such a way that a small form factor can be maintained. The structure includes spacer substrate 820 which is typically affixed to the bottom surface 6 of the base substrate. The spacer substrate includes an opening 834 therein for accommodating the optical isolator. The opening is typically a cut-out portion extending completely through the spacer substrate. The optical isolator prevents lightwaves from reflecting backwards into the sealed volume 810 and allows for stable, low noise optical emissions. The optical isolator 818 includes a garnet and a half wave plate in the opening 834. The opening in the spacer substrate may be formed, for example, by etching, drilling, or dicing techniques. The spacer substrate may be formed, for example, of a glass such as Schott BK-7 (Schott North America, Inc., Elmsford, N.Y. USA), Pyrex™ glass (Corning Inc., Corning, N.Y. USA) or the like. As with the base substrate and lid, the spacer substrate and integrated optical isolator structures may be formed on the wafer-level.

With additional reference to example FIG. 11, the device package lid 808 is formed of a material which is selected based on desired characteristics of the package, for example, gas permeability, optical properties and coefficient of thermal expansion (CTE). The lid may, for example, be formed of any material suitable for use in packaging of electronic devices such as semiconductor materials and glasses. Typically, the substrate material includes a single crystalline semiconductor material such as single-crystalline silicon, silicon-on-insulator or silicon-germanium. Etched, stamped or otherwise-formed metals can also serve as the lid. An exemplary metal for use in the lid is tantalum, which has a CTE close to that of silicon.

The lid is of a size sufficient to enclose the desired portion of the base substrate front surface. A typical length and width for a rectangular ceiling portion is, for example, on the order of from about 1 to about 50 mm. As with the base substrate, the lid substrate can be in wafer-form, making possible the simultaneous manufacture of multiple lids. The resulting base substrate wafers and lid wafers can be assembled together on the wafer-level.

The lids 808 of the device packages may be processed prior to attachment to the base substrate to include solder wick stops 842, 844, an etched cavity 836, a beam turning mirror 816, seal ring metallurgy 838, alignment fiducials 840, solder wick stops 842, 844, dicing indicators or fiducials 846 and a hermeticity indicator.

Suitable techniques for forming a lid with a cavity from single-crystalline materials using anisotropic etching techniques are known. In the exemplified package, turning mirror 816 is integrated into the lid as a chemically etched crystal plane which forms an inner surface of the lid, on which is formed a layer of reflective (with respect to the emitted light) material. A suitable reflective material in the case of near IR wavelengths is gold. The turning mirror allows for turning/bending of a beam emitted from an edge emitting laser out-of-plane through the base substrate. In this way, vertical coupling of the emitted beam with an external optical assembly comprising an optical waveguide, for example, a PIC and/or a PLC can be realized. As used in the context of a PLC or PIC substrate, “vertical” refers to the angle of incidence of the laser beam with respect to the plane of the PLC or PIC substrate. Such angle can be substantially normal (90°) or a selected non-normal angle with respect to the base substrate. This angle will depend, for example, on the angle of the turning mirror with respect to the incident angle of the light beam. The angle can be adjusted, for example, by selection of a suitable substrate material, crystallographic orientation and etching pattern and conditions.

The lid also can include a metal sealing ring 838 for forming a seal, typically a hermetic seal, with the base substrate. The lid sealing ring 838 should be of similar geometry to the base substrate sealing ring 830. The same materials described for the base substrate sealing ring may be used for the lid sealing ring. The lid and base substrate sealing rings may be joined, for example, using a solder such as a Au—Sn solder in an inert environment, such a helium, nitrogen, or argon.

As shown in example FIG. 11, one or more solder wick stops in the form of an etched groove can be formed in the lid to prevent solder used to seal the lid to the base from flowing into regions that would impact operation of the package. For example, wick stop 842 formed in the lid outside the sealing ring 838 in a position which will lie over the conductive traces of the base substrate can prevent solder from flowing outward under the lid which could otherwise short circuit and contaminate the conductive traces and/or wire bond pads. Similarly, wick stop 844 formed in the lid between the sealing ring 838 and the turning mirror prevents solder from flowing onto the turning mirror 16, thus avoiding the problem of obscuring the beam.

The lids may be made from a material such as silicon or SOI allowing the lid top surface to have a controlled thickness. This is useful to allow the lid to serve as a leak sensor by choosing a thickness that will cause a know bulge when a pressure of helium is sealed inside, or when the sealed device is bombed in helium. In such a case, the lid effectively becomes a pressure gauge that can aid in determining the exact leak rate against the gases sealed inside or the ability of the package to resist a pressure of gas such as helium applied outside the package for a period of time. Such deflections can be measured on an interferometer such as those made by Wyko and Zygo Corporation. Also, a specific region of the lid may be thinned to serve as a deflection membrane.

For wafer-level processing, the lids may be attached individually to the device substrate or, more typically, in wafer form. The process of sealing the lid may involve baking the lid and base substrate with the bonded optoelectronic component in a controlled environment, for example, with an inert gas such as He, Ar, or N₂ or under vacuum, to remove any water vapor present. Pressure may then be applied between the lid and base substrate and the part is heated to the reflow temperature of the metal solder of the sealing rings. Optionally, the pressure may be applied after the reflow temperature is reached. It may be beneficial to seal under a pressure of He such that when cooled, the sealed area has a pressure significantly higher than atmospheric pressure. This technique will allow for monitoring the level of hermeticity or leak rate in the package at any time subsequent to making the hermetic seal.

Assembly of the hermetic laser package can optionally be performed through a combination of wafer-scale and wafer-grid level assembly to reduce assembly and test cost as well as to achieve improved tolerances and precision. Example FIG. 12 illustrates a view of a wafer-level optoelectronic device package in accordance with embodiments. As shown, a grid of the packages may be formed on a single wafer. Optionally, the lid and base wafers may be diced into smaller rectangular arrays (or grids) prior to attaching the lids to the base substrate. Such smaller arrays can, for example, contain sites for about 16 to 40 device packages such as about 32 device packages.

Optionally, a portion of the lid 808 may be removed from the lid wafer to expose contact pads 828. The exposed contact pads become accessible to test probes, allowing for wafer-level bum-in and testing for functional optical- and electrical requirements. This aspect results in testing which can be conducted in a simplified and automatic manners, a reduction in handling of individual parts and a reduction in test time. In the case of a wafer-level manufacturing process, the device packages formed as multiple die are singulated, for example, by dicing through the base substrate, spacer substrate and lid substrate between adjacent packages.

With reference to example FIG. 13, the optoelectronic package 801 allows vertical coupling of a beam from the optoelectronic device into a waveguide 848 of a PLC or PIC chip 852. It should be clear that the PLC or PLI chip as illustrated is a simplified rendering thereof, showing a single waveguide. Not shown, for example, are additional waveguides or electrical function. The laser package may be aligned with lateral (xy) and rotational (theta) alignments to couple the beam from the optoelectronic device into the waveguide. Following alignment of the optoelectronic package, it can be secured to the PLC and/or PIC chip, for example, with use of an epoxy or by localized reflow of a solder using a high power laser. Alignment and attachment of the device package to the waveguide device can thus be accomplished in a precise and simple manner, and providing a high coupling efficiency.

The illustrated turning mirror of the device package may be left out of the structure. In the case of an edge-emitting laser device, the optical beam may pass through an etched window formed in a side of the lid. The optical beam can then be incident in the plane of the optical waveguides, for example, edge coupling of the light into the optical waveguides that extend to the edge of the PLC or PIC chip. In such a case, the light transmissive materials described above with respect to the base substrate may be used for the lid, with single-crystal silicon being typical. As an alternative where no mirror is present, the edge emitting device can be replaced with a surface emitting laser, in which case the laser can be mounted in such a way that the light beam is directed through the base substrate.

In accordance with embodiments, it is envisioned that the optoelectronic device can be mounted on the package lid rather than the base substrate.

The optoelectronic device packages, in accordance with embodiments, are typically continuous waver (cw) constant optoelectronic devices, for example, for PIC applications but the packages may also be modulated. In such a case, electrical connections to the optoelectronic device can be designed for controlled impedance, including thin/thick film resistors, to match the impedance of the modulation source to the laser. In such a case, the hermetic laser package can be a high speed (bit rates of up to 40 Gb/s or more) modulated laser package for direct modulation of the laser.

Prism-coupled optical assemblies and their methods of formation will now be described with reference to example FIGS. 14-17, depicting an optical assembly in accordance with embodiments. The optical assembly 902 includes an optical package 904 attached to a planar lightwave circuit substrate 906 which includes an integrated optical waveguide 908. The optical package 904 includes a base substrate 909 which may be, for example, a single-crystalline silicon or silicon-on-insulator substrate. The optical package includes one or more optical components. The optical components may include active and/or passive devices, for example, one or more of light sources, detectors, optical fibers, waveguides, fiber couplers, isolators and lenses.

The illustrated package includes a precision flip-chip bonded laser die 910, an anti-reflection-coated ball lens 912, for example an approximately 400 μm diameter cubic zirconia lens, bonded to a wet-etched facet 913 and an optical isolator 914 which may be cut to fit groove 915 in the base substrate 909. A prism formed in the base substrate provides optical coupling to the integrated optical waveguide 908 of the PLC substrate. The optical package 904 may further include a wet-etched silicon lid 918 and a bonding ring 920 joining the lid to the base substrate to provide a hermetically enclosed volume 922. Optionally, the prism can be formed in the lid if the lid is precisely bonded to the base.

An etched region 924 in the back of the base substrate contains solder bumps 926 for electrically connecting the optical package to electrical traces on the PLC substrate 906. Electrical connection from the optical package 4 may be accomplished using conductive vias through the base substrate 909. Alternatively, electrical traces extending along the base substrate under the lid 918 may be used if the base substrate is longer than the lid, and a passivation layer, for example, of silicon nitride and/or silicon oxide is used over the feedthrough traces. In such case, the device can be wire bonded to the PLC substrate 906 for electrical connection.

The light travels from the laser die 910 through the ball lens 912, through the isolator 914, and into the opposing, smaller facet 928 of the prism in the base substrate. The angle of this facet from the surface plane of the substrate determines the angle of refraction of the light. Various crystallographic orientations for the silicon of the base substrate may be used depending on the desired angle of refraction of light. For example, anisotropically etched <100> and <110> silicon wafers provide a facet having an angle from the surface plane of the substrate of about 54.74 degrees and about 45 degrees, respectively. If another angle is desired, one may use wafers from a <100> or <110> silicon ingot which has been sliced off-axis. The illustrated base substrate is a <110> silicon wafer sliced off-axis and having a facet angle greater than the typical 54.74 degrees. Depending on the desired angle, the angle that the lens 912 makes can be made correspondingly more or less shallow by adjusting its height position along. After the light enters the facet 928 of the prism, it is refracted downward to the waveguide 908.

A total-internal-reflection (TIR) condition is established at the base of the prism by air or a low index material before the waveguide core in the PLC substrate 6 is reached. The interaction length between the waveguide core and the prism is set by the angle of incidence and the thickness of the low index material. Evanescent coupling between the reflected mode in the prism and the waveguide mode allows the light to transfer from the prism to the waveguide 908.

Example FIG. 17 is a top down view of the waveguide coupling region 930, the downtapers 932, and the final waveguide dimension 934 on the right. Two waveguides and downtaper regions are shown, which can be used when the index of the prism and the index of the waveguide used in the PLC are of similar refractive index, or when the index of the prism is less than the index of the PLC waveguide. Reference to an “index” or “refractive index” with respect to the integrated optical waveguide is actually the effective index of the waveguide. The coupling region in the case shown has a lower taper made from silicon that transitions from, for example, an approximately 50 μm waveguide width to an approximately 0.3 μm silicon waveguide on the right. The inner coupling region may be a silicon nitride waveguide, about 45 μm in width and about one millimeter long. The nitride waveguide may have a silicon nitride thickness from about 0.5 to several microns and may be clad by silicon dioxide below, and optionally above it, that is from about 0.25 to about 1 μm thick.

When the prism coupler is aligned to alignment marks created in the same lithographic step as the waveguides on the PLC substrate 906, it can very accurately be placed on the surface. The light thus couples from the prism into the silicon nitride waveguide. The light propagates in the silicon nitride waveguide through that waveguide's downtapered region. The mode in the downtaper is eventually squeezed out and couples into the silicon waveguide, which continues the down taper to the final dimensions of the silicon PLC circuit. All the materials and dimensions are given by way of example, and in a real application the thicknesses, taper shapes and lengths, would all be calculated using the integrated optics modeling software or using design equations from papers referenced earlier. It should be clear that use of a secondary top waveguide is optional and not necessary, for example, when the index of the prism is greater than the effective index of the waveguide to which light is to be coupled.

The high-index prism may be formed, for example, by silicon micromachining using anisotropic crystallographic etching. In this case, optical devices such as a mounted laser, photodiode, or optical fiber may be disposed on or in the surface of the silicon. One or more lenses and/or other optical mode shaping components may be mounted in or on the silicon, or formed from the silicon. The light can be launched into a <111> or other crystalline facet that is anisotropically etched to a smooth optical surface that serves as a launching facet 928 of an integrated coupling prism formed by the facet and a bottom surface of the silicon substrate.

Reflections from the facet of the prism can be reduced or controlled to required values using one or more antireflective coatings. Such coatings include, for example, a silicon oxynitride quarterwave layer, silicon nitride and silicon oxide multilayer coatings, or other materials with thicknesses calculable and well known in the art of optical interference coatings.

Such a submount thus allows light to travel to or from an optical device such as a laser, photodetector or waveguide mounted on or in the prism coupling component to optically couple in and out of the planar waveguide substrate on which the prism coupling device is mounted.

Unique advantages possible with this technology include the ability of leveraging many known techniques in making and assembling silicon optical bench components, such as integration of solder, thick film microelectronics, hermetic lids or non-hermetic coatings, precision alignment marks, passive alignment features, precision v-grooves and pits, dry-etched mechanical features, micro-optics and isolators, electrical vias, and the like, combined with the ability to have an integrated method of creating the coupling prism monolithically in the submount itself using anisotropic etching. This allows the practical and cost effective production of light sources, fiber couplers, detectors, and even PLCs created in, on, and from these submounts with their integrated prism couplers all formed as discreet components that can be formed and tested and then precision bonded to, for example, a wafer full of many silicon waveguide planar lightwave circuits. In addition, such an arrangement can further be used to test the planar lightwave circuits themselves at the wafer level, before the bonding operation, wherein the assembly system does not bond the prism coupled assembly unless the planar lightwave circuit tests as “good”.

In order to create a prism coupling technology based that can couple to a large variety of waveguide configurations, the ability to precisely control the mode shape, focal width, and angle of incidence of the incoming light incident on the prism surface, is needed. When using crystallographic etching this can be accomplished using one or more methods including adjusting the position of the coupling lens with respect to the component being coupled, for example raising or lowering the center position of a ball lens with the output facet of a semiconductor laser can change the incident beam angle on an opposing silicon facet. Furthermore, modeshapes can be adjusted using tapers and beam expanders on the laser and/or using anamorphic lenses or binary optical lenses in the beam path.

As described above, greater degree of control on the angle of incidence between the optical component and the prism facet can be obtained by the use of custom sliced “off-axis” silicon wafers. In this approach, the wafers are sliced at a specified non-normal angle to the silicon ingot's axis. This approach allows <110> wafers to produce wet etched <111> facets that are non-perpendicular to the wafer surface and allows <100> wafers to produce wet etched <111> facets that are offset from the typical 54.74 degrees down from the wafer's surface. This approach allows complete customization of the prism angles as needed for optimal phase matching to any particular PLC configuration.

Additional requirements for prism coupling include control of the low-index gap between the prism and the waveguide to which it will couple. In traditional prism couplers, this is a ˜λ/4 air gap between the prism and the waveguide and the thickness sets the coupling length for a particular incident angle of light. While airgaps can be used for these applications, it is often desirable to have a filled region between the prism coupling device and the waveguide. This can be accomplished by filling the region with an adhesive, gel, or a low index coating such as SiO₂. In some cases, it would be desirable to use the low index region also to bond the devices together. This can be accomplished, for example, using an optical adhesive by setting the low index ˜λ4 gap using etched standoffs on the back mounting face of the prism coupler or on the waveguide device being coupled to. For example, dry etching silicon or SiO₂ can readily produce such stand-off pedestals outside of the coupling region. Alternatively, the required gap can be produced by bonding two films together such as by covalent bonding of two SiO₂ films deposited on each of the mating surfaces through techniques as commercialized by Ziptronix, Inc.

In most cases, the beam produced by the prism-coupling device will be very large compared to the nominal waveguide core size for the planar lightwave circuit. In the case of silicon photonics, such waveguide cores typically range from about 0.2 to several microns in width. The incident beam, however, is often from about 100 to about 300 μm full width, when producing a collimated beam using fiber or laser sources and high index lenses such as a ball lens made from cubic zirconia with diameters of from about 200 to about 600 microns. For example, a typical DFB laser produces a 200 μm beam in cross-section when placed at the focal point of an approximately 400 μm cubic zirconia ball lens. In such cases, the mode size of the waveguide region is typically first expanded using an “up-taper” region. Such uptapers and their variants have been described in the art. By having a shallow angle of expansion of the waveguide, a single mode coupling region can be produced allowing, for example, the beam focused on the mating facet of the prism with a spot size of from about 10 to about 50 μm width to have a phase matching interaction in a region from about 200 μm to several millimeters in length. Once the light is transferred into the expanded region of the waveguide, the gradual taper in the waveguide can nearly adiabatically transfer the optical power into the nominal waveguide cross-section. An analysis for finding the optimal size of the beam in the matching region, the coupling length, and the optimal waveguide dimension in the coupling region, and tradeoffs for beam size and waveguide dimensions for relaxed positioning accuracy between the prism and the waveguide are within the abilities of one of ordinary skill in this field

When coupling the prism coupler to a waveguide it is often desirable for the prism to have a significantly higher refractive index than the effective index of the waveguide to which it will couple. In the case of a silicon prism coupling to a silicon based waveguide, added flexibility to the coupling scheme can be made by depositing a secondary waveguide with a tapered region having a lower refractive index on top of the silicon photonic waveguide in the interaction region between the prism and the waveguides. For example, a silicon nitride coupling region with a silicon dioxide cladding that transitions to a down taper can be deposited on top of a silicon waveguide having a second downtaper. In this case, the light from the prism coupler first couples to the lower refractive index waveguide, for example, silicon nitride. After coupling from the prism into the nitride waveguide, the light then enters a downtaper region in the silicon nitride waveguide which then transfers the light into the underlying silicon waveguide. The silicon waveguide continues the taper to the nominal silicon waveguide core dimensions. It should be clear that while a direction is described for purposes of description, such processes are typically reciprocal and the same downtapers serve as uptapers for optical power traveling from the waveguides into the prism. Design of adiabatic waveguide tapers is well known in the art and there are various techniques for engineering both the size and the shape of modes through such transitions by precision etching of the waveguide core and one or more surrounding layers.

There are various paths to producing the optical assemblies in accordance with embodiments. An exemplary design and manufacturing process is described as follows. First an optical model of the prism coupler, the other components in the optical trail, and the waveguide to be coupled to are analyzed using a combination of ray tracing, Maxwell's equations solvers, and beam propagation methods. Considerations examining the angle of incidence required, the interaction length between the prism and the waveguide, the loss associated with the taper, the size of the waveguide in the coupling region when compared to the positioning tolerances for X,Y,Z and rotation available in the assembly tool, the application of intermediate lower effective index waveguides between the prism and the base waveguide, the positional tolerances of all optical components in the optical trail, and so on. Typically a Monte Carlo simulation is used to examine the combination of these effects including the all mechanical component and assembly tolerances, and then design adjustments are made to ensure a high cumulative yield.

Once an optical and mechanical analysis is complete, the silicon optical bench with the integrated prism coupler is designed. Depending on the analysis results, the part may best be produced using off-axis sliced silicon wafers, which allow the prism coupling facet, typically a <111> wet etched plane in silicon, be chosen.

An exemplary process for making the optical package will now be described. An off-axis <100> silicon wafer is coated with a low-stress silicon-rich silicon nitride film. Metal features are deposited using a metallization scheme such as chrome (about 25 nm), nickel (about 300 nm), gold (about 1000 nm). The metals are patterned using photoresist by either lift-off or wet etching. Fiducials for aligning the components can be created in the metal layer or etched into the surface. Next an opening in the silicon nitride film is created using photolithography and plasma etching. The wafer is etched in an anisotropic silicon etchant such as KOH or TMAH to produce the needed grooves and or pits. The exposed prism facet created by wet etching is then antireflection-coated using LPCVD, PECVD or other known methods.

The back side of the substrate can be stripped in a plasma etch and the coupling gap can be set by etching into the silicon or a film on the back side of known thickness to create a series of mechanical stops or pedestals outside the coupling region. If the part will be attached using an oxide bonding method, a blanket oxide film can be deposited instead with the thickness of the low index phase-matching coupling region set by the combination of this oxide thickness and the oxide thickness on the waveguide to which the prism will be coupled. Finally a thin film solder, typically something of approximate composition of 80%-20% Au—Sn is applied in layers to the submount and patterned either by etching, lift-off, or shadow masking. Various other steps can be included depending on the desired final configuration. For example, hermetic vias may be made for electrically connecting the device, ring metals may be deposited to attach a hermetic lid, aluminum layers may be deposited for solid state oxide bonding of optical components, and so forth. In cases where a lid or base or sidewall is described, alternate crystallographic or lapped surfaces can be used. For example, light from a laser mounted on a surface of a substrate or lid may be coupled into a lens mounted on base or lid surface, and the light may be coupled to any controlled exposed angular or lapped surfaces on the substrate or lid, allowing the prism and the components in the optical trail to be aligned as desired. Many permutations of these configurations are possible in the art of silicon micromachining. Furthermore, each of the foregoing steps may be conducted at the wafer level.

Next, the optical components may be populated onto the prism subassembly. The population of these parts can occur after singulation of the prism coupler wafers, but typically occurs beforehand and may be conducted at the wafer level. These steps include, for example, precision flip-chip bonding of laser die using a ˜1 μm accuracy die bonder using a passive vision alignment system, bonding the lens to the desired height using etched features in the prism sub-assembly, and bonding any other optical elements, such as an isolator in the optical path. In the case of coupling to an optical fiber or a photodetector, the components may be bonded in the region of the laser and various techniques can be leveraged to position them in the desired location as known in the art of silicon optical bench. For example, a v-groove can be etched to position an optical fiber.

Next, electrical connections can be made such as wedge or wire bonding of the active devices, if required. Alternatively, the electrical connections may be made during the previous attach process if flip-chip electrical contacts are provided. Finally the devices can be protected from the environment using a hermetic lid or by applying a “glop-top” coating over the components.

Where a laser is present on the first substrate, the components can then be burned-in and tested at the wafer level using a probe array. In this way, early failures can be eliminated. After burn-in and testing, the parts may be singulated with a dicing saw or by cleaving, thus providing the individual packaged prism-coupler optical assemblies, ready for application.

The application of these components would typically occur by placing them using a precision bonder, similar to the laser die placement. A tool such as the FC-250 (S.E.T.-SAS, France) is capable of attaching multiple die on 8-inch or larger substrates with ±0.5 μm accuracy. In this case the tool will pick the prism coupling components, align them to fiducials on a top or bottom surface, or may use IR illumination to directly detect the fiducials used for laser die placement. The bonder then attaches the prism-coupler device to the wafer of integrated optics using fiducials on the integrated optic wafer that can be defined in the same lithographic step as the waveguide coupling region. Bonding may be performed, for example, by adhesive attachment. In an exemplary such technique, a several microliter drop of optical adhesive may be placed on the PLC wafer and/or prism-coupler, and the bonder thermally or UV cures the part in position. Alternatively, a solder attach which may optionally also provide electrical interfacing, may be used to permanently attach the component. Other variations are possible, including for example, oxide to oxide covalent bonding.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. An optoelectronic device package, comprising:
a first substrate having a first surface and a second surface opposite the first surface;
a lid over the first surface forming an enclosed volume between the lid and the first surface;
an optoelectronic device in the enclosed volume;
a second substrate facing the second surface, the second substrate having an opening therein; and
an optical isolator disposed in the opening;
wherein the optoelectronic device package has an optical path that passes through the first substrate and the optical isolator.

2. The optoelectronic device package of claim 1, comprising:
one or more wick stops in the first substrate and/or the lid for controlling the flow of metal solder during formation of the optoelectronic device package.

3. The optoelectronic device package of claim 1, further comprising a turning mirror in the enclosed volume for reflecting light to or from the optoelectronic device, wherein the turning mirror comprises a metal layer formed on an interior surface of the lid and the groove is for preventing solder contamination of the mirror during formation of the optoelectronic device package.

4. The optoelectronic device package of claim 1, wherein the first substrate and the lid comprise single-crystal-silicon.

5. The optoelectronic device package of claim 3, further comprising a ball lens in the enclosed volume between the optoelectronic device and the turning mirror.

6. The optoelectronic device package of claim 1, wherein the optical path through the first substrate is at a non-normal angle.

7. The optoelectronic device package of claim 1, further comprising a metal sealing ring surrounding the enclosed volume and through which the lid is attached to the substrate, wherein the one or more wick stops comprises a groove formed in the lid adjacent and internal to the metal sealing ring.

8. The optoelectronic device package of claim 1, wherein the one or more wick stops comprise a groove formed in the base substrate and/or lid, wherein the groove contains residual solder remaining after formation of the optoelectronic device package.

9. An electronic device package, comprising:
a sealed enclosure;
an electronic device disposed in the sealed enclosure; and
a conductive feedthrough allowing an electrical signal to pass into and/or out of the sealed enclosure;
wherein the sealed enclosure comprises:
a first substrate having a surface on which first and second conductor segments are disposed, and an electrically discontinuous region on the surface between the first and second conductor segments; and
a spacer circumscribing the electronic device, the spacer comprising the conductive feedthrough, wherein the conductive feedthrough electrically connects the first and second conductor segments.

10. The electronic device package of claim 9, wherein the sealed enclosure further comprises a second substrate spaced apart from the first substrate, wherein the spacer is disposed between the first and second substrates.

11. The electronic device package of claim 10, wherein the spacer is formed in part of the second substrate.

12. The electronic device package of claim 9, wherein the electronic device is a MEMS device.

13. The electronic device package of claim 9, wherein the first substrate comprises a metal seal ring on the surface disposed between and electrically isolated from the first and second conductor segments, and wherein the spacer is bonded to the metal seal ring.

14. A prism-coupled optical assembly, comprising:
a first substrate comprising a prism for coupling light into an integrated optical waveguide;
an optical component on and/or in the first substrate; and
a second substrate comprising an integrated optical waveguide optically coupled to the optical component and prism, wherein the first substrate is attached to the second substrate and an optical path extends through the first substrate.

15. The prism-coupled optical assembly of claim 14, wherein the optical component is an optoelectronic device and further comprising a lens on and/or in the first substrate, wherein the lens is disposed in an optical path between the optoelectronic device and the prism.

16. The prism-coupled optical assembly of claim 15, wherein the lens is attached to a sloped surface formed in the first substrate, the sloped surface allowing for attachment of the lens at any selected height along the sloped surface.

17. The prism-coupled optical assembly of claim 14, wherein the prism is monolithic to the first substrate.

18. The prism-coupled optical assembly of claim 14, wherein the first substrate comprises an off-axis cut <100> or <110> single-crystal-silicon.

19. The prism-coupled optical assembly of claim 14, further comprising a lid on the first surface to form a sealed volume which hermetically encloses the optical device.

20. The prism-coupled optical assembly of claim 1, further comprising an optical material disposed between the first substrate and the second substrate, the optical material having an index of refraction less than that of the first substrate and the integrated optical waveguide.
